(19) United States
(12) Patent Application Publication
(10) Pub. No.: US 2014/0347070 A1
(43) Pub. Date: Nov. 27, 2014

(54) Measuring Method Using a Measuring Apparatus for Cable Diagnosis and/or Cable Testing

(71) Applicant: Hagenuk KMT Kabelmesstechnik GmbH, Radeburg (DE)

(72) Inventors: Sven SCHEUSCHNER, Radeburg (DE); Torsten BERTH, Moritzburg (DE); Frank PETZOLD, Baunach (DE)

(73) Assignee: Hagenuk KMT Kabelmesstechnik GmbH, Radeburg (DE)

(21) Appl. No.: 14/251,916

(22) Filed: Apr. 14, 2014

(30) Foreign Application Priority Data
May 22, 2013 (DE) 10 2013 008 968.9

(51) Int. Cl. G01R 31/08

(52) U.S. Cl. CPC G01R 31/08
USPC 324/543

(57) ABSTRACT

A measuring apparatus is connected to a cable to perform testing and diagnosis of the cable. The measuring apparatus includes a voltage source, a resistance, a switch, and an inductance forming a charging circuit, and two anti-parallel thyristors or switched diodes together with the inductance forming a series resonant circuit loop. The apparatus produces a low frequency alternating voltage signal train including a low frequency test signal followed by a low frequency diagnostic signal. The diagnostic signal is a damped decaying signal oscillation in the resonant circuit connected to the test cable. At least one of the signals is bipolar. Both cable testing and cable diagnosis can be performed using the same single measuring apparatus in a single measuring procedure.

### PRIORITY CLAIM

This application is based on and claims the priority under 35 USC 119 of German Patent Application 10 2013 008 968.9, filed on May 22, 2013, the entire disclosure of which is incorporated herein by reference.

### FIELD OF THE INVENTION

The invention relates to a measuring method using a measuring apparatus for performing cable diagnosis and/or cable testing of an electrical cable, by applying to the cable a low frequency alternating voltage signal train comprising a diagnostic signal and/or a test signal.

### BACKGROUND INFORMATION

It is important to determine the electrical characteristics of an electrical cable, such as a medium voltage power distribution cable, in order to be able to ensure the fault-free and interference-free operation of a network having a cable system including the cable at issue. On the one hand, the cable can be subjected to so-called cable testing, in which the cable is tested for functionality, e.g. by determining any existing damage of a cable jacket or sheath, whereby for example the main insulation (conductor insulation) is subjected to a voltage test. On the other hand, the cable can be subjected to so-called cable diagnosis, in which cable characteristics such as the capacitance and the polarization characteristics, which represent indicators of cable aging or degradation processes that progress over time, can be determined and the cable can additionally be examined for partial discharges.

While both cable testing and cable diagnosis are important procedures, it has previously fundamentally been necessary to carry out these two procedures with separate distinct devices performing separate distinct test procedures and diagnostic procedures. That generally has caused significant effort and expense due to the need for several different pieces of equipment, and due to the additional time for personnel to connect the different devices and carry out the distinct procedures.

For cable diagnostics, the test object, such as a medium voltage cable for example, is typically charged up or loaded linearly with a voltage, and is subsequently interrogated or measured by means of a damped voltage.

In conventional measuring apparatuses using a low frequency alternating voltage signal train, the test measurement typically is carried out with a very low frequency (VLF) testing technology and method. For an explanation of the basic principles of the VLF testing technology, reference is made to the German Patent Publications DE 44 13 585 C2 and DE 44 37 355 C2, of which the entire content and disclosure are incorporated herein by reference.

A very good overview and explanation of the basic technical principles of an oscillating wave test system (OWTS) for cable diagnosis can be obtained from the publication “Transmission Power Cables PD Detection at Damped AC Voltages” by E. Gulski et al. in JICABLE '03 International Conference on Insulated Power Cables, 2003.

In conventional technologies known from the prior art, and especially in the OWTS technology for cable diagnosis, test object cables are impinged upon or loaded in a unipolar manner, i.e. with a unipolar DC or direct voltage. In this regard, the duration of the DC voltage loading is determined by the power or the output current of the high voltage source in relation to the cable capacitance of the cable that is to be tested, which depends on the cable length and other factors. As a result, especially for very long cables, this necessarily (as a limitation of the system) leads to a very long duration of the DC voltage loading, for example up to several minutes, which is not acceptable. Such a conventional procedure can damage the cable, for example due to polarization effects, that is to say space charge formation. Moreover, the cable testing and the cable diagnosis cannot be carried out by means of a single method, but rather several separate distinct measuring apparatuses are necessary for carrying out separate distinct measuring processes.

### SUMMARY OF THE INVENTION

In view of the above, it is an object of an embodiment of the invention, to improve methods of the general type discussed above, in order to provide a method that can perform both cable diagnosis and cable testing by generating and applying to the cable a combination of a test signal and a diagnostic signal. A further object of an embodiment of the invention is to provide a measuring apparatus by which such a combined test and diagnostic signal can be produced and applied to a test object such as a cable. Another object of an embodiment of the invention is thus to enable both the testing and diagnosis of a cable using a single measuring apparatus in a single measuring process. The invention further aims to avoid or overcome the disadvantages of the prior art, and to achieve additional advantages, as apparent from the present specification. The attainment of these objects is, however, not a required limitation of the claimed invention.

The above objects can be achieved in an embodiment of the invention in which the test signal comprises a low frequency alternating voltage that establishes a required or specified nominal voltage, the diagnostic signal comprises a low frequency alternating damped oscillation that subsequently follows the test signal, and the test signal and/or the diagnostic signal is respectively a bipolar signal.

An embodiment of the invention is directed to a method of testing and/or diagnosing an electrical cable, comprising steps:
a) connecting a measuring apparatus including a signal application device to an electrical cable;
b) with the signal application device producing and applying to the cable, a low frequency alternating voltage test signal at least until reaching a terminal voltage level which is a nominal prescribed voltage level or a partial discharge voltage level, and then discontinuing the test signal;
c) after the test signal reaches the terminal voltage level, with the signal application device producing and applying to the cable, a low frequency alternating voltage diagnostic signal that comprises a damped oscillation following the test signal; and
d) with the measuring apparatus connected to the electrical cable measuring at least one electrical characteristic;
   wherein the at least one electrical characteristic is relevant for testing and/or diagnosing the electrical cable, and wherein at least one of the test signal and the diagnostic signal is a bipolar signal.

In another embodiment of the invention, a measuring method uses a measuring apparatus for cable diagnosis and cable testing with a signal application device, which produces a low frequency alternating voltage signal train with a low frequency test signal and a low frequency diagnostic signal following the test signal, characterized in that a nominal required voltage is achievable by an alternating voltage, and a damped oscillation follows as the diagnostic signal, whereby the low frequency test signal and/or the low frequency diagnostic signal is embodied bipolar.

In another embodiment according to the invention, a measuring apparatus for testing and/or diagnosing an electrical cable comprises first and second test leads adapted to be connected to the electrical cable, an electrical energy source connected between the first and second test leads, a switch and an inductor interposed in series with one another between the electrical energy source and the first test lead, and an anti-parallel circuit arrangement of two thyristors or of two diodes and two switches, wherein the anti-parallel circuit arrangement is connected to the second test lead and to a circuit node between the switch and the inductor.

With the above features and/or others as disclosed herein, embodiments of the invention make it possible to carry out a cable testing as well as a cable diagnosis using a single signal application apparatus in a single measuring procedure. Additionally, by using a damped diagnostic signal, an especially gentle or protective as well as effective measuring method is provided. By using an alternating voltage signal train, an unnecessary loading of the cable is avoided, and a gentle bipolar oscillating ramp-up or increase of the voltage up to the test voltage is made possible. Moreover, the use of a low frequency test signal over a prescribed test period makes it possible to measure, evaluate and recognize thermal effects in the test cable.

The following discussion will explain certain terminology and concepts pertinent for this application.

The term “cable testing” refers to a method for determining a functionality of a cable. In this regard, the functionality of the cable is determined over a prescribed testing time period with a prescribed test voltage level. According to an embodiment of the present invention, the very low frequency (VLF) testing technology can preferably be used for carrying out the cable testing.

The prescribed testing time period is to be understood as a time period that is prescribed for the cable testing in corresponding technical specifications or regulations. In particular preferred embodiments of the invention, the testing time period for a cable test of a medium voltage cable using VLF testing technology is in the range from 30 minutes to 60 minutes. With such a testing time period, it is also possible to evaluate thermal effects in the cable for determining the functionality of the cable.

The term “cable diagnosis” or “cable diagnostics” refers to a method for determining a momentary condition or present existing condition of the cable, such as for example an aging condition, during a diagnostic time period. According to preferred embodiments of the invention, the OWTS technology is used for performing the cable diagnosis. Furthermore, several individual measuring methods or processes can be combined for determining the condition of the cable. For example, according to preferred embodiments of the invention, a tan-delta los measurement and a partial discharge measurement can be combined for performing the cable diagnosis.

The diagnosis time period or diagnostic time period is a freely selectable time period in which a diagnostic signal exists on the cable. The diagnostic time period is considerably shorter than the testing time period, and can lie in a range from 1 second to minutes, for example, in preferred embodiments of the invention.

The “signal application device” is preferably an apparatus that produces or prepares an electrical signal from an electrical energy source, and supplies the prepared electrical signal to the cable and/or imposes the prepared electrical signal on the cable, for carrying out the cable testing and/or the cable diagnosis.

The term “low frequency” refers to a signal, especially an electrical signal, of which the significant or essential spectral signal components respectively comprise a frequency of less than (or no more than) 20 kHz. In this regard, the signal may be composed of one or more sinusoidal oscillations of one or more frequencies. In this regard, one or more sinusoidal oscillations of a frequency form the spectral signal component of or at this frequency. Preferred embodiments of the invention may use a square wave signal or rectangular wave signal, or a modified square or rectangular wave signal. In preferred embodiments, the frequency may be 500 Hz or less for the low frequency signal.

In this regard, “significant” or “essential” spectral signal components are preferably understood to include the spectral signal components of which the spectral power density amounts to at least 10% of the spectral power density of the signal component having the maximum spectral power density.

The term “alternating voltage signal train” refers to a succession of several electrical signals or signal pulses or signal oscillations, of which the electrical voltage alternately changes its polarity.

The term “test signal” refers to an electrical signal used for the cable testing.

The term “diagnostic signal” refers to an electrical signal used for the cable diagnosis.

In order to achieve a measuring result that is close to reality, the low frequency test signal and/or the low frequency diagnostic signal may comprise a signal flank that corresponds to a network signal flank, for example such a network signal flank that arises in reality during the typical operation of the cable.

In this regard, a “signal flank”, especially of a square wave or rectangular wave signal, refers to a temporal signal segment in which the signal rises from 10% of its peak-to-peak value to 90% of its peak-to-peak value (rising flank), or falls from 90% of its peak-to-peak value to 10% of its peak-to-peak value (falling flank). For a sinusoidal signal, the signal flank is understood to refer to a rising signal portion at the inflection point.

The term “network signal flank” refers to the flank of an electrical signal that is applied or is to be applied to the cable for the electrical power supply to electrical consumers in an energy or power supply network. In a preferred example embodiment, a network signal flank refers to the signal rise at the zero crossing of an alternating voltage with a frequency of 50 Hz or 60 Hz in the power supply network.

The term “corresponding” (and similar terms) is understood to allow deviations and/or differences of up to 30% from exact equivalence. It is advantageous if the deviations and/or differences amount to at most 10%. It is especially advantageous and preferred if the deviations and/or differences amount to at most 5%.

In a further example embodiment, the test signal rises or increases over time from a lower starting value to a nominal prescribed voltage level (or to a partial discharge voltage level if a partial discharge is initiated by the testing). Thereby, a rising or increasing loading and/or testing of the cable can be achieved, and a sudden voltage jump and/or pulse loading can be avoided. More particularly, in further detailed embodiment features, the test signal can rise continuously and smoothly, or can rise in a stepped manner.

In another example embodiment of the invention, further alternating voltage signals follow after the alternating voltage signal train that includes the test signal followed by the diagnostic signal. In this manner, in an especially simple and efficient way, it is possible to carry out several cable test procedures and/or cable diagnosis procedures sequentially after one another, without any loss or waste of time. Simultaneously, thereby a statistical evaluation and analysis result can be provided regarding the results of the cable testing and/or cable diagnosis, and thereby measurement errors can be minimized.

In a further embodiment of the measuring apparatus and of the measuring method according to the invention, the diagnostic signal comprises a diagnostic starting voltage that preferably corresponds to a minimum value of a negative period of a test signal voltage, or a maximum value of a positive period of the test signal voltage, or an intermediate voltage value of the test signal voltage at which the test signal ends. In other words, that is to say the diagnostic signal preferably continuously and smoothly adjoins the test signal in that the diagnostic signal smoothly begins at the voltage level at which the test signal ends. Thereby, voltage jumps and/or voltage peaks in the transition from the test signal to the diagnostic signal are avoided. Furthermore it is thereby possible to reduce a risk of an undesired loading and/or damaging of the cable during this transition.

In a further example embodiment of the invention, the signal application device of the measuring apparatus comprises an electronic switching element, which preferably comprises at least one thyristor in a preferred embodiment, which is preferably operated continuously for producing the low frequency diagnostic signal. Through the use of the electronic switching element, especially the thyristor, it is possible to realize a compact low-wear construction of the measuring apparatus, and it is possible to keep the switching times particularly short. By continuously operating the thyristor for producing the low frequency diagnostic signal, it is possible to produce an uninterrupted and uniform alternating diagnostic signal. Thereby the risk of an undesired loading and/or a damaging of the cable can be reduced.

### BRIEF DESCRIPTION OF THE DRAWINGS

In order that the invention may be clearly understood, it will now be explained in further detail in connection with example embodiments thereof, with reference to the accompanying drawings, wherein:

FIG. 1 is a schematic diagram of a measuring system including a cable as a test object as well as a measuring apparatus having a signal application device and an electrical energy source; and

FIG. 2 is a graph schematically representing the progression of voltage (U) over time (t) of a low frequency alternating voltage signal train including a low frequency test signal followed by a low frequency damped diagnostic signal.

### DETAILED DESCRIPTION OF PREFERRED EXAMPLE EMBODIMENTS AND THE BEST MODE OF THE INVENTION

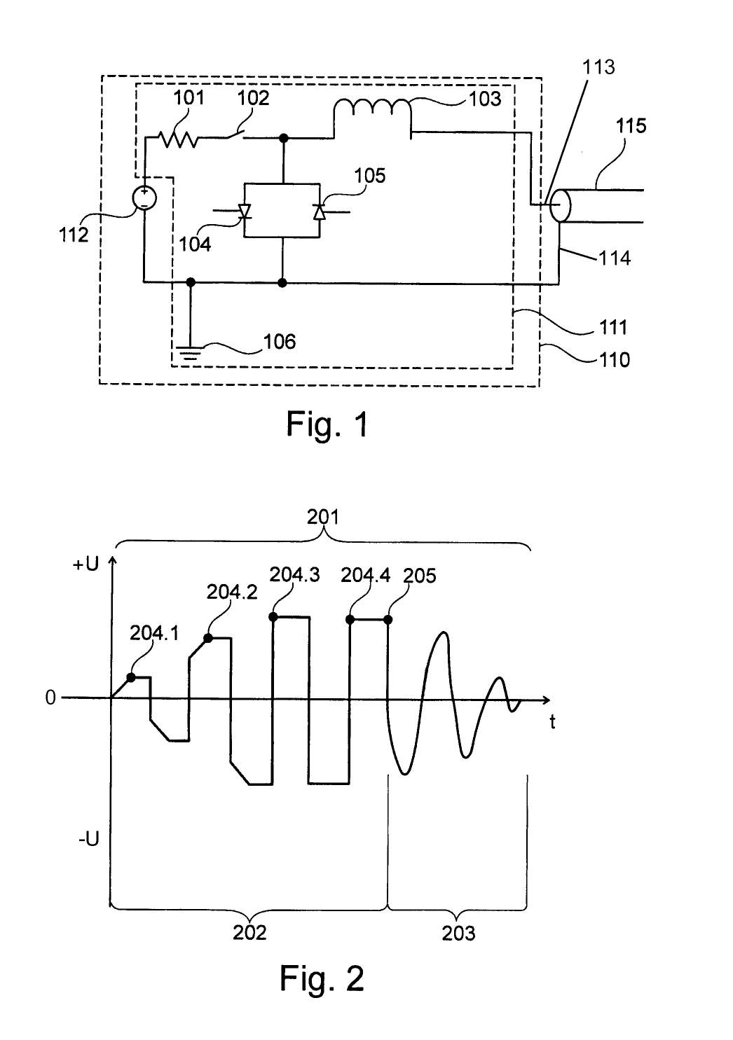

The measuring system schematically illustrated in FIG. 1 includes a measuring apparatus 110 and a test object represented schematically by a cable 115. The measuring apparatus 110 includes an electric energy source 112, such as a direct or DC voltage source, and a signal application device 111.

The signal application device 111 comprises an electrical resistor or resistance 101 circuit-connected to the electrical energy source 112 and in series with a switch 102, as well as a choke coil or inductor or inductance 103 connected in series between the switch 102 and a first test lead 113, which connects the device 111 with an inner central conductor of the cable 115. It should be understood that the resistor or resistance can be a single resistor component, or a plurality of resistor components, or any individual component or arrangement of plural components that provides the required total resistance value. Similarly, the inductor or inductance can be a single inductor component, or a plurality of inductor components, or any individual component or arrangement of plural components that provides the required total inductance value. The electrical energy source 112 in the present illustrated embodiment is embodied as a direct or DC voltage source, and the resistance 101 serves to protect the electrical energy source 112 against return traveling waves and against overloading.

An outer sheath of the cable 115 is connected by a second test lead 114 of the device 111, to an electrical ground or earth 106, which is also connected to the electrical energy source 112. Thus, the electrical energy source 112, the resistor 101, the switch 102, the choke coil or inductor 103, the test leads 113 and 114, the inner conductor and the outer sheath of the cable 115 together form a series charging circuit.

Furthermore, the signal application device 111 additionally comprises a first thyristor 104 and a second thyristor 105 that are connected anti-parallel to one another (i.e. parallel in opposite current flow directions), and in series with the choke coil 103 between the two test leads 113 and 114. Namely, the anti-parallel arrangement of the two thyristors 104 and 105 is connected between the ground 106 and a circuit node between the switch 102 and the choke coil 103. In an alternative embodiment, instead of the thyristors 104 and 105, the signal application device 111 includes two diodes arranged anti-parallel and coupled with mechanical switches to provide a similar switching function as the thyristors in the illustrated example embodiment. In either embodiment, this arrangement serves to form a resonant circuit loop with the cable 115, as will be discussed below.

With the above circuit arrangement, the signal application device 111 serves to produce and apply to the cable 115 a test signal as well as a damped diagnostic signal, as will be explained next in connection with FIG. 2.

The graph of FIG. 2 shows the time progression of the voltage level U over time t of a low frequency alternating voltage signal train 201 that includes both the test signal 202 and the damped diagnostic signal 203 which directly follows the test signal 202. The maximum voltage of the test signal 202 is built up successively over several intermediate voltage values 204.1, 204.2 and 204.3 to ultimately reach the maximum voltage 204.4, which preferably corresponds to the initial or starting voltage value 205 of the diagnostic signal 203. Namely, the diagnostic signal 203 begins with the diagnostic initial voltage 205 and then decays oscillatingly from there.

In order to test the cable 115 and especially to determine a so-called inception voltage and a so-called extinction voltage of a partial discharge (PD) occurring in the cable 115, the voltage of the test signal 202 is successively increased in defined steps, e.g. 204.1, 204.2, 204.3 during the cable testing procedure. If this results in the initiation or inception of a partial discharge in the cable 115 then the PD inception voltage has thereby been determined. Then the voltage can be reduced to determine the extinction voltage at which the partial discharge is extinguished. Thereby the pertinent voltage levels and other parameters for the partial discharge in the cable can be determined. On the other hand, if the test signal voltage value is step-wise increased up to the maximum voltage 204.4 as the nominal prescribed voltage level of the test signal 202, without triggering a partial discharge, i.e. if the maximum voltage 204.4 lies below the PD inception voltage, then the PD inception voltage will not be determined. In other words, in such a situation, it will not be possible to determine the inception voltage of a partial discharge. However, it is not absolutely necessary to reach the PD inception voltage, because if the maximum voltage 204.4 of the test signal 202 was sufficiently high for the specifications or technical regulations of the cable 115, without triggering a partial discharge with this test signal 202, then the cable 115 is thereby determined to be fully functional up to the required specifications or regulations.

For carrying out the testing and diagnosis of the cable 115, the measuring apparatus 110 is connected by the electrical test leads 113 and 114 to the cable 115 as shown in FIG. 1. Then, for charging the cable 115 with the test signal 202, the switch 102 is closed (switched on), and a current flows from the electrical energy source 112 through the resistance 101, the switch 102 and the choke coil 103 to the inner conductor of the cable 115, whereby the cable 115 is charged up to the intermediate voltage value 204.1 of the test signal 202. During this charging phase, both thyristors 104 and 105 are opened (switched off). The inner conductor and the outer sheath of the cable 115 together form a capacitance that depends on the length of the cable among other factors. Thus, this capacitance of the cable is charged up to the intermediate voltage value 204.1 of the test signal 202.

Once the cable 115 has been charged up to the intermediate voltage value 204.1 of the test signal 202, then the switch 102 is opened (switched off) so as to interrupt the current flow from the electrical energy source 112. At this time, the first thyristor 104 is closed (switched on) while the second thyristor 105 remains open (switched off), which leads to a reversal of the test signal 202 flowing back through the inductor 103 and the thyristor 104, which is seen in FIG. 2 by the falling flank and the negative signal portion of the test signal 202 following attainment of the intermediate voltage 204.1. Following this, the second thyristor 105 is closed (switched on) and the first thyristor is opened, which causes a return oscillation of the test signal 202. At this time, in order to further charge the cable 115 up to the higher intermediate voltage value 204.2 of the test signal 202, the switch 102 is again closed (switched on). Thus, a current supplied from the electrical energy source 112 through the switch 102 supplements the return oscillation current flowing through the second thyristor 105, to charge the cable 115 further up to the higher intermediate voltage 204.2.

The above described process is repeated in succession to charge the cable successively to higher intermediate voltage values 204.3 and 204.4 until a required or prescribed nominal test voltage level, e.g. 204.4, of the test signal 202 is reached. This allows a partial discharge inception to be determined at or before reaching the prescribed test voltage level 204.4, or allows approval of the cable as passing the test to the required standards. Thus, the terminal or final voltage of the test signal 202 is the nominal prescribed test voltage level or an earlier-reached partial discharge voltage level (e.g. the PD inception voltage). For this also, it is possible to repeat the charging cycle at the prescribed test voltage level for as long as is required by the prescribed test period. Alternatively, the above described process can be repeated so long until the required nominal voltage level of the starting or initial voltage 205 of the diagnostic signal 203 is reached.

In any event, once the testing with the test signal 202 has been completed and/or the required initial voltage 205 for the diagnostic signal 203 has been reached, then the cable diagnosis begins with the initial voltage 205 corresponding to the final or terminal voltage of the test signal 202. At this time, both thyristors 104 and 105 are closed (switched on). Thereby, current can flow freely back and forth through the thyristor arrangement, in the series resonant circuit loop formed by the thyristors 104 and 105, the inductor 103 and the capacitance of the cable 115. Thereby the damped diagnostic signal 203 is produced as a current passively resonantly oscillates back and forth in this resonant loop, and the cable diagnosis is thereby carried out. This oscillation of the diagnostic signal 203 in this resonant circuit is damped by the circuit characteristics (especially including the cable characteristics), whereby the decay is determined by the inherent resistance of the circuit components, conductive connections, and the cable 115, and the oscillation frequency is determined by the inductance of the choke coil 103 and the capacitance of the cable 105. The capacitance of the cable 115 is now determined based on the oscillation frequency of the damped diagnostic signal 203. Also, especially the tan-delta loss factor and further cable characteristics are determined from the signal progression and the decay behavior of the damped diagnostic signal 203.

After the complete decay (or decay below a minimum voltage level) of the damped oscillation of the diagnostic signal 203, the above described procedure for charging up the cable 115 by application of the test signal 202 is again started. Thereby, another cycle of the cable testing procedure and the cable diagnosis procedure can be performed as desired. The results of two or more of such successive cable test procedures and cable diagnosis procedures are then evaluated, and can be averaged for example, in order to determine the relevant characteristics of the cable with increased accuracy. Also, different test procedures and/or diagnostic procedures can be carried out in succession top provide additional information, or to provide an error check of the first test and diagnosis procedures. The measuring apparatus may include further devices (not illustrated) for measuring electrical characteristics such as voltage, current, frequency, time duration, damping, decay, etc., as well as a temperature sensor for measuring a temperature of the cable to be used in evaluating temperature induced effects on the cable characteristics. The measuring apparatus may further include at least one processor, at least one memory, at least one input device, and at least one output device, for measuring, calculating, evaluating, comparing, or otherwise processing parameters of the cable. The measuring apparatus can be embodied in or as a single unit or in plural units that are connectable as a system.

Although the invention has been described with reference to specific example embodiments, it will be appreciated that it is intended to cover all modifications and equivalents within the scope of the appended claims. It should also be understood that the present disclosure includes all possible combinations of any individual features recited in any of the appended claims. The abstract of the disclosure does not define or limit the claimed invention, but rather merely abstracts certain features disclosed in the application.

What is claimed is:

1. A method of testing and/or diagnosing an electrical cable, comprising steps:
a) connecting a measuring apparatus including a signal application device to an electrical cable;
b) with said signal application device producing and applying to said cable, a low frequency alternating voltage test signal at least until reaching a terminal voltage level which is a nominal prescribed voltage level or a partial discharge voltage level;
c) after said test signal reaches said terminal voltage level, with said signal application device producing and applying to said cable, a low frequency alternating voltage diagnostic signal that comprises a damped oscillation following said test signal; and
d) with said measuring apparatus connected to said electrical cable, measuring at least one electrical characteristic;
wherein said at least one electrical characteristic is relevant for testing and/or diagnosing said electrical cable, and wherein at least one of said test signal and said diagnostic signal is a bipolar signal.

2. The method according to claim 1, wherein said step b) further comprises increasing said test signal from a lower starting voltage up to said terminal voltage level during a voltage increasing period.

3. The method according to claim 1, wherein said step b) comprises reaching said nominal prescribed voltage level, and further comprises continuing to apply said test signal at said nominal prescribed voltage level during a predetermined test period, and in said step c) said diagnostic signal continues during a diagnosis period.

4. The method according to claim 3, wherein said predetermined test period has a duration in a range from 30 minutes to 60 minutes, and said diagnosis period has a duration in a range from 1 second to 5 minutes.

5. The method according to claim 1, wherein said diagnostic signal begins smoothly and continuously at an end voltage level at which said test voltage ends.

6. The method according to claim 1, wherein
said measuring apparatus further includes an electrical energy source connected to said signal application device,
said signal application device includes a resonant circuit loop connected to said electrical cable,
said producing of said test signal comprises alternately switching a current flow direction in said resonant circuit loop while correspondingly alternately switching on and off a current flow from said electrical energy source to said resonant circuit loop so as to successively actively increase a voltage level of successive alternating signal pulses of said test signal up to said terminal voltage level, and
said producing of said diagnostic signal comprises switching off said current flow from said electrical energy source and passively allowing alternating oscillating resonant decay of said diagnostic signal as said damped oscillation following said test signal.

7. The method according to claim 1, further comprising evaluating said at least one electrical characteristic to determine a test result of said testing and a diagnostic result of said diagnosing of said electrical cable.

8. The method according to claim 7, wherein said test result indicates a functionality or non-functionality of said electrical cable, and said diagnostic result indicates a present momentary condition of said electrical cable.

9. The method according to claim 7, wherein said terminal voltage level is said nominal prescribed voltage level and said test result indicates that said electrical cable has successfully withstood said test signal at said nominal prescribed voltage level during a predetermined test period duration without suffering a partial discharge, or said terminal voltage level is said partial discharge voltage level and said test result indicates that said electrical cable has suffered a partial discharge inception at said partial discharge voltage level.

10. The method according to claim 7, wherein said diagnostic result indicates at least one of a capacitance of said electrical cable, an oscillation frequency of said damped oscillation of said diagnostic signal, a tan delta loss factor of said electrical cable, and a decay coefficient of said damped oscillation of said diagnostic signal.

11. The method according to claim 1, wherein both said test signal and said diagnostic signal are bipolar.

12. The method according to claim 1, further comprising, after said step c), producing and applying additional diagnostic signal trains following said diagnostic signal.

13. The method according to claim 12, further comprising performing a plurality of different diagnostic evaluations in succession after one another.

14. The method according to claim 1, further comprising measuring and evaluating thermal effects in said electrical cable.

15. The method according to claim 1, wherein said signal application device comprises at least one thyristor, and said producing of said diagnostic signal comprises operating said at least one thyristor to be continuously active.

16. A measuring method using a measuring apparatus for cable diagnosis and cable testing with a signal application device, which produces a low frequency alternating voltage signal train with a low frequency test signal and a low frequency diagnostic signal following the test signal, characterized in that a nominal required voltage is achievable by an alternating voltage, and a damped oscillation follows as the diagnostic signal, whereby the low frequency test signal and/or the low frequency diagnostic signal is embodied bipolar.

17. A measuring apparatus for testing and/or diagnosing an electrical cable, said measuring apparatus comprising:
first and second test leads adapted to be connected to the electrical cable,
an electrical energy source connected between said first and second test leads,
a switch and an inductor interposed in series with one another between said electrical energy source and said first test lead, and
an anti-parallel circuit arrangement of two thyristors or of two diodes and two switches respectively in series with one another, wherein said anti-parallel circuit arrangement is connected to said second test lead and to a circuit node between said switch and said inductor.

18. The measuring apparatus according to claim 17, wherein said anti-parallel circuit arrangement comprises said two thyristors connected anti-parallel to each other.

19. The measuring apparatus according to claim 17, wherein said electrical energy source is a DC voltage source.

20. The measuring apparatus according to claim 17, further comprising a resistor interposed between said electrical energy source and said switch.
